(19) United States
(12) Patent Application Publication
(10) Pub. No.: US 2011/0121463 A1
(43) Pub. Date: May 26, 2011

(54) SEMICONDUCTOR PACKAGE, SEMICONDUCTOR DEVICE AND METHODS OF THE SAME

(75) Inventors: John Clarimer Vicente CONCEPCION, Hyogo-ken (JP); Takao Nogi, Hyogo-ken (JP)

(73) Assignee: Kabushiki Kaisha Toshiba, Tokyo (JP)

(21) Appl. No.: 12/880,053

(22) Filed: Sep. 10, 2010

(30) Foreign Application Priority Data
Nov. 20, 2009 (JP) 2009-264648

(51) Int. Cl. H01L 23/48; H01L 21/58

(52) U.S. Cl. 257/774; 438/125; 257/E23.011; 257/E21.505

(57) ABSTRACT

According to one embodiment, a semiconductor package is disclosed. The semiconductor package can include an insulative substrate having a first surface and a second surface opposed to the first surface, a first through hole formed in the insulative substrate from the first surface to the second surface, and a second through hole formed near the first through hole in the insulative substrate from the first surface to the second surface, a conductive body formed in the vicinity of the second through hole and penetrating into the insulative substrate, a first outer electrode formed on the first surface and connected to an one end of the conductive body, and a second outer electrode formed on the second surface and connected to the other end of the conductive body.

### CROSS REFERENCE TO RELATED APPLICATION

This application is based upon and claims the benefit of priority from prior Japanese Patent Application No. 2009-264648, filed on Nov. 20, 2009, the entire contents of which are incorporated herein by reference.

### FIELD

Exemplary embodiments described herein relate to a semiconductor package, a semiconductor device and methods of fabricating semiconductor package and the semiconductor device.

### BACKGROUND

Recently, kinds of small-type electronics represented by a cell phone or a mobile digital assistance have been popularized.

In such a progress, a surface mounting type package in which an electrode lead can be directly soldered to a substrate has been a main stream in resin encapsulation type semiconductor devices.

In conventional semiconductor process, a semiconductor chip is disposed on a mount head of a lead frame. Next, the semiconductor chip is connected to a lead terminal using a wire. Subsequently, the semiconductor chip and the wire is molded by a resin.

In the conventional semiconductor device, the wire is looped, so that a height of the semiconductor device can hardly be lowered. This is a problem in the conventional case.

On the other hand, a semiconductor device which is lower in height without the wire has been known.

The semiconductor device includes multi-level thin layers including dielectric layers and re-wiring layers, a semiconductor chip connected to the re-wiring layers and mounted in the multi-level thin layers, a conductive structure body connected to the re-wiring layers and formed as a pillar state on a surface of the multi-level thin layers, a molding portion partially formed on the multi-level thin layers and covering the conductive structure body and the semiconductor chip, a bump for connecting between an outer portion and the conductive structure body.

In the semiconductor device, the molding portion is formed by grinding an upper surface of the resin covering the structure and the semiconductor chip.

As a result, a problem in which processing steps are increased and become complexity is generated.

Accordingly, a problem in which a production of the semiconductor device has a long time and heavy cost is generated.

### BRIEF DESCRIPTION OF THE DRAWINGS

FIG. 1A is a plane view showing a semiconductor package and FIG. 1B is a cross sectional view showing the semiconductor package cut along the A-A line in FIG. 1A and viewed towards the arrowed direction according to a first embodiment;

FIG. 2A is a plane view showing a semiconductor device partially cut away and FIG. 2B is a cross sectional view showing the semiconductor device cut along the B-B line in FIG. 2A and viewed towards the arrowed direction according to the first embodiment;

FIG. 3A is a diagram showing characteristics of the semiconductor device according to the first embodiment and FIG. 3B is a diagram showing characteristics of the semiconductor device according to a conventional case for comparing between the first embodiment and the conventional case;

FIGS. 4A-4C are cross sectional views showing a method of fabricating the semiconductor package in an order of processing steps according to the first embodiment;

FIGS. 5A-5B are cross sectional views showing the method of fabricating the semiconductor package in the order of processing steps according to the first embodiment;

FIGS. 6A-6C are cross sectional views showing the method of fabricating the semiconductor device in the order of processing steps according to the first embodiment;

FIGS. 7A-7C are cross sectional views showing the method of fabricating the semiconductor device in the order of processing steps according to the first embodiment;

FIGS. 8A-BC are cross sectional views showing the method of fabricating the semiconductor device in the order of processing steps according to the first embodiment;

FIG. 9 is a cross sectional views showing the semiconductor device mounted on a substrate according to the first embodiment;

FIG. 10 is a cross sectional views showing another semiconductor device according to the first embodiment;

FIG. 11A is a plane view showing a semiconductor package and FIG. 1B is a cross sectional view showing the semiconductor package along the c-c line in FIG. 11A and viewed towards the arrowed direction according to a second embodiment;

FIGS. 12A-12C are cross sectional views showing a method of fabricating the semiconductor device in an order of processing steps according to the second embodiment;

FIG. 13 is a cross sectional views showing a semiconductor device according to a third embodiment;

FIGS. 14A-14C are cross sectional views showing a method of fabricating the semiconductor device in an order of processing steps according to the third embodiment.

### DETAILED DESCRIPTION

According to one embodiment, a semiconductor package is disclosed. The semiconductor package can include an insulative substrate having a first surface and a second surface opposed to the first surface, a first through hole formed in the insulative substrate from the first surface to the second surface, and a second through hole formed near the first through hole in the insulative substrate from the first surface to the second surface, a conductive body formed in the vicinity of the second through hole and penetrating into the insulative substrate, a first outer electrode formed on the first surface and connected to an one end of the conductive body, and a second outer electrode formed on the second surface and connected to the other end of the conductive body.

Embodiments will be described below in detail with reference to the attached drawings mentioned above. It should be noted that the present invention is not restricted to the embodiments but covers their equivalents. Throughout the attached drawings, similar or same reference numerals show similar, equivalent or same components.

### First Embodiment

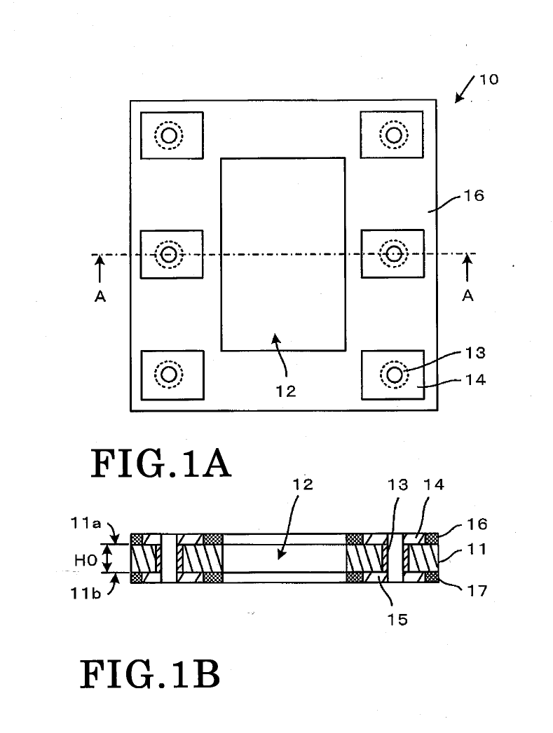

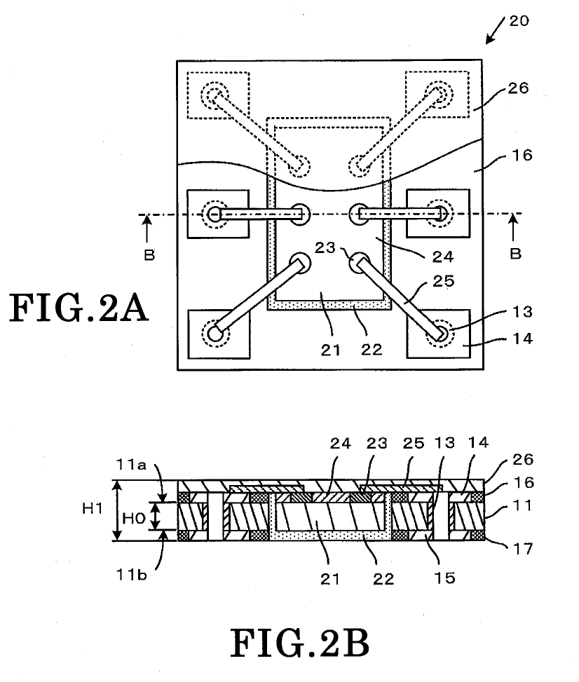

A first embodiment is explained as reference to FIG. 1 and FIG. 2. FIG. 1A is a plane view showing a semiconductor package and FIG. 1B is a cross sectional view showing the semiconductor package cut along the A-A line in FIG. 1A and viewed towards the arrowed direction according to a first embodiment. FIG. 2A is a plane view showing a semiconductor device partially cut away and FIG. 2B is a cross sectional view showing the semiconductor device cut along the B-B line in FIG. 2A and viewed towards the arrowed direction according to a first embodiment.

In this embodiment, a semiconductor package for surface-mounting a semiconductor chip including a planer-type diode, a transistor or the like and a semiconductor device resin-encapsulated in the package are demonstrated.

First, a semiconductor package is explained. As shown in FIG. 1, a through hole 12 is formed in an insulative substrate 11 through from a first surface 11a to a second surface 11b opposed to the first surface 11a in a semiconductor package 10 of this embodiment. A semiconductor chip (not shown) is stored in the through hole 12.

The insulative substrate 11 is a glass epoxy substrate, for example. The insulative substrate 11 is constituted with layered closes made of glass fibers and an epoxy resin is penetrated therein. The insulative substrate 11 has a width of 2-5 mm and a thickness H0 of 0.2-1 mm, for example, the thickness H0 is nearly the same as a thickness of the semiconductor chip stored in the through hole 12.

A plurality of conductive bodies 13 are formed around the through hole 12 and pass through the insulative substrate 11 from the first surface 11a to the second surface lib. Each of the conductive bodies 13 is constituted with a through hole, for example, obtained by plating copper (Cu) on a side surface of the through hole formed in the insulative substrate 11.

A first external electrode 14 is formed on the first surface 11a to cover one edge portion of conductive body 13 and is contacted to one end of the conductive body 13. The first external electrode 14 is made of a Cu-plated film with a thick of nearly several micrometers.

A second external electrode 15, as the same as the first external electrode 14, is formed on the second surface 11b to cover the other edge portion of conductive body 13 and is contacted to the other end of the conductive body 13. The second external electrode 15 is made of a Cu-plated film with a thick of nearly several micrometers.

A resist film or a polyimide film, for example, is formed on a portion of the first surface 11a other than the first external electrode 14. An insulative film 16 is formed both to protect and to planarize the first surface 11a of the insulative substrate.

A resist film or a polyimide film, for example, is formed on a portion of the second surface 11b other than the second external electrode 15, as the same as the first surface 11a. An insulative film 17 is formed both to protect and to planarize the second surface 11b of the insulative substrate.

The semiconductor package 10 is constituted to package a semiconductor chip which is stored in the through hole 12. An upper surface and a lower surface of the semiconductor chip is covered with a resin.

Next, a semiconductor device is explained below. As shown in FIG. 2, a semiconductor chip 21 of a semiconductor device 20 is stored in the through hole 12 according to this embodiment.

A space between a side surface of the semiconductor chip 21 and a side surface of the through hole 12 is filled with a resin 22, for example, an epoxy resin. The semiconductor chip 21 is fixed to the side surface of the through hole 12 through the resin 22.

The resin 22 is also formed on the lower surface at a side of the second surface 11b of the semiconductor chip 21 to be the same height as the second external electrode 15.

An electrode 23 is formed on an upper surface at a side of the first surface 11a in the semiconductor chip 21. A polyimide film, for example, is formed on the upper surface other than the electrode 23 as a protective film 24 in the semiconductor chip 21.

The protective film 24 is formed both to protect the semiconductor chip and to planarize the upper surface of the semiconductor chip 21.

The electrode 23 is connected to the first external electrode 14 through a connection conductor 25. The connection conductor 25 is formed as a conductive plate, for example, a Cu plate. Both ends of the connection conductor 25 are bonded to the electrode 23 and the first external electrode 14, respectively, by ultra sonic bonding.

Further, a resin 26, for example, an epoxy resin, is formed at a side of the first surface 11a of the insulative substrate 11 to cover the semiconductor chip 21, the first external electrode 14 and the connection conductor 25.

In such a manner, both the upper surface and the lower surface of the semiconductor chip 21 are covered with the resin 26 to be packaged in the semiconductor package 10. As a result, a height H1 of the semiconductor device 20 set to be a thickness which is added the thickness of the insulative substrate 11 H0, a thickness of the resin 22 and a thickness of the resin 26.

The thickness of the semiconductor device 20 H1 is set to be nearly 260 μm, when the thickness of the insulative substrate 11 H0 is 0.2 mm, the thickness of the resin 22 is several micrometers which is nearly the same as the thickness of the second external electrode 15, the thickness of the resin 26 is nearly 50 μm, for example, which can cover the connection conductor 25 with a thickness of nearly 30 μm. The semiconductor device being quite thin can be obtained in this method.

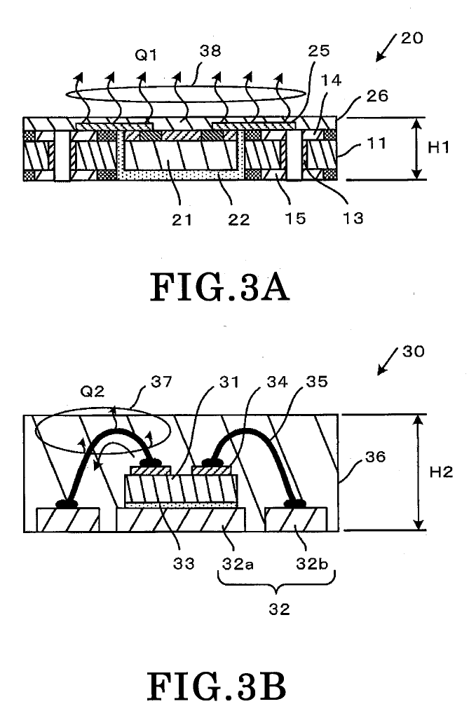

FIG. 3A is a diagram showing characteristics of the semiconductor device according to the first embodiment and FIG. 3B is a diagram showing characteristics of the semiconductor device according to a conventional case for comparing between the first embodiment and the conventional case. Here, the conventional case represents a semiconductor device in which a semiconductor chip connected to an electrode lead by a wire. First, the conventional case is explained.

As shown in FIG. 3B, a semiconductor chip 31 is fixed to a mount head 32a of a lead frame 32 through an adhesive layer 33 in a semiconductor device 30 as the conventional case. An electrode 34 of the semiconductor chip 31 is connected to a lead terminal 32b by a wire 35. The semiconductor chip 31 and the wire 35 is inextricably molded by a resin 36

In the semiconductor device 30, the wire 35 is looped corresponding to a distance between the semiconductor chip 31 and the lead terminal 32b. Accordingly, a height H2 of the resin 36 is set to be higher due to the height of the wire 35.

Further, the wire 35 has a small surface area and small thermal conductivity and is surrounded by the resin 36, consequently, heat dispassion 37 from the wire 35 is small.

Further, a cross section area of the wire 35 also is small, therefore, the wire 35 is less heat conduction, and heat dispassion from the lead terminal 32b is small.

On the other hand, as shown in FIG. 3B, in the semiconductor device 20 of the embodiment, the thickness of the resin 26 may be a thickness in which the upper surface of the connection conductor 25 is not exposed, the height H1 of the semiconductor device 20 is sufficiently lowered as compared to the height H2 of the semiconductor device 30 as the conventional case.

As a width of the connection conductor 25 is freely configured in the range without connecting to the neighboring connection conductor, a surface area of the connection conductor 25 is larger as compared to the wire 35. As the resin 26 is thin, heat dispassion 38 from the connection conductor 25 can be larger.

Further, the cross section area of the connection conductor 25 is larger than that of the wire 35, consequently, heat is easily conducted in the connection conductor 25 and heat dispassion through the second electrode 14 and the conductive body 13 second electrode 15 can be larger.

Accordingly, the height H1 of the semiconductor device 20 is higher than the height H2 of the semiconductor device 30 as the conventional case. Further, the heat dispassion amount Q1 of the semiconductor device 20 is higher than the heat dispassion amount Q2 of the conventional semiconductor device 30. Therefore, the semiconductor device in the embodiment can obtain miniaturization and higher heat dispassion.

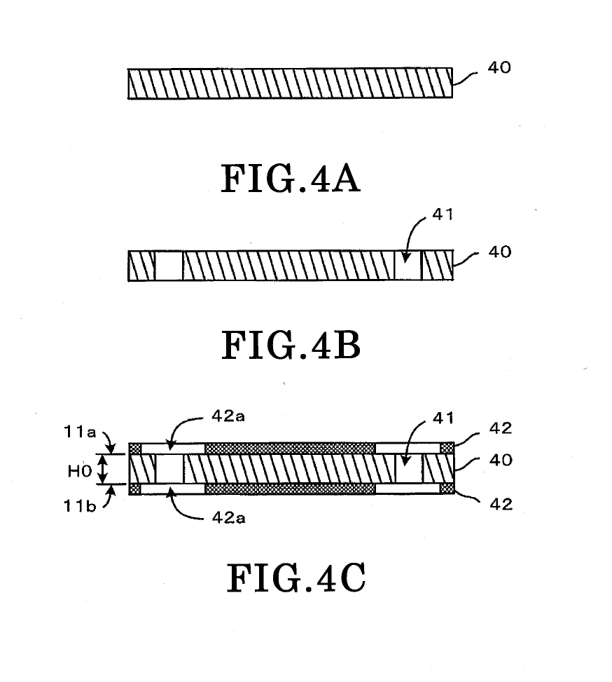

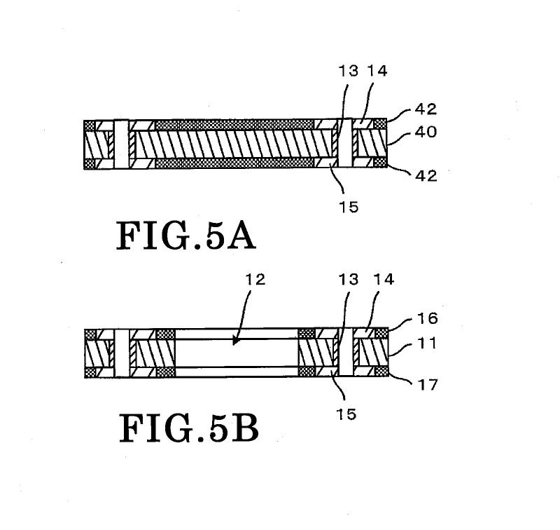

Next, a method of fabricating the semiconductor package is explained below. FIGS. 4 and 5 are cross sectional views showing a method of fabricating the semiconductor package in an order of processing steps according to the first embodiment.

As shown in FIG. 4A, a glass epoxy substrate 40 as the insulative substrate 11 is prepared. As shown in FIG. 4B, the glass epoxy substrate 40 is holed by a drill, for example, to form a plurality of through holes 41 in the glass epoxy substrate 40 for forming the conductive body 13.

As shown in FIG. 4C, resist films 42 are formed on both surfaces of the glass epoxy substrate 40 and an opening 42a is patterned in a concentric fashion with a through hole 41 for forming the second electrode 14 and the second electrode 15 by photo-lithography

A thickness of the resist film 42 is set to be nearly several micrometers which is nearly the same as the thicknesses of the first external electrode 14 and the second external electrode 15.

As shown in FIG. 5A, Cu films are formed on both surface of the glass epoxy substrate 40 by electroplating. Successively, the resist film 42 is leaved on the surface to be the insulative films 16, 17.

Here, underlying plating is preliminary carried out on a side surface of the through hole 41, the first surface 11a exposed in the opening 42a at a side of the first surface 11a and the second surface 11b exposed in the opening 42a at a side of the second surface 11b.

A Cu film plated on the side surface of the through hole 41 becomes the conductive body 13 of the through hole.

A Cu film plated on the first surface 11a exposed in the opening 42a at the side of the first surface 11a becomes the first external electrode 14 which is connected to one end of the conductive body 13. A Cu film plated on the second surface 11b exposed in the opening 42a at the side of the second surface 11b becomes the second external electrode 15 which is connected to the other end of the conductive body 13.

As shown in FIG. 5B, an area surrounded by conductive body 13 in the glass epoxy substrate 40 is cut by laser processing apparatus, for example, or is holed by a drill to form the through hole 12.

In such a manner, the semiconductor package 10 including the insulative substrate 11 with the through hole, the conductive body 13 formed in the vicinity of the through hole 12, the second electrode 14 connected to one end of the conductive body 13 and the second electrode 15 connected to the other conductive body 13, is obtained.

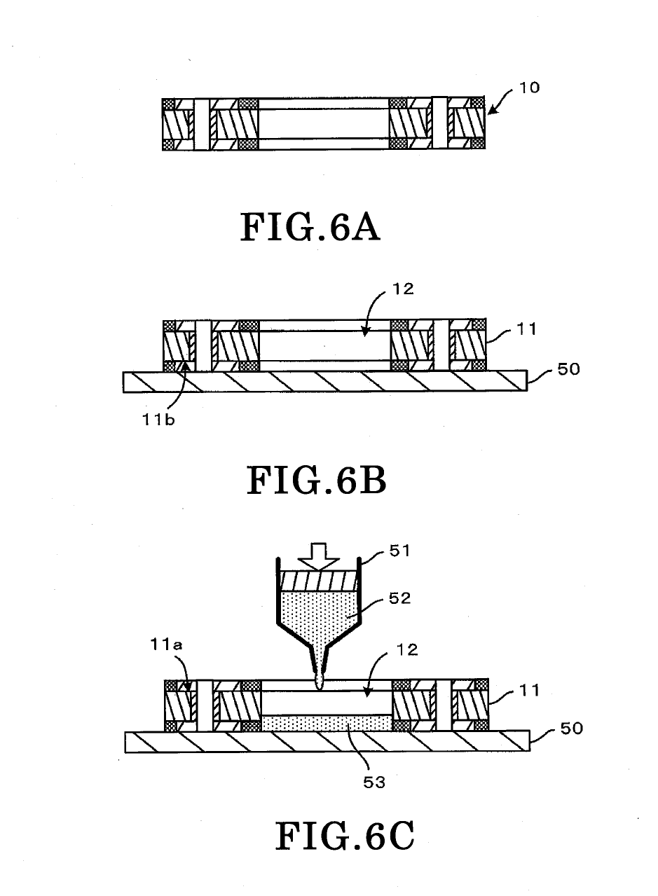

Next, a method of fabricating the semiconductor device 20 is explained below. FIGS. 6-8 are cross sectional views showing a method of fabricating the semiconductor device in an order of processing steps according to the first embodiment.

As shown in FIG. 6A, the semiconductor package 10 is prepared. As shown in FIG. 6B, the second surface 11b of the insulative substrate 11, is opposed to a polyimide sheet 50 in which a surface area is formed as an adhesive layer, so that the semiconductor package 10 is stuck to the polyimide sheet 50. In such a way, the second surface 11b of the through hole 12 is covered by the polyimide sheet 50.

As shown in FIG. 6C, a liquid resin 52, for example, an epoxy resin, is fallen in drops from the side of the first surface 11a of the through hole 12 by using a dispenser 51, for example. As the second surface 11b of the through hole 12 is covered with the polyimide sheet 50, a liquid resin 53 fallen on the polyimide sheet is pooled in the through hole without dropping to an outer portion.

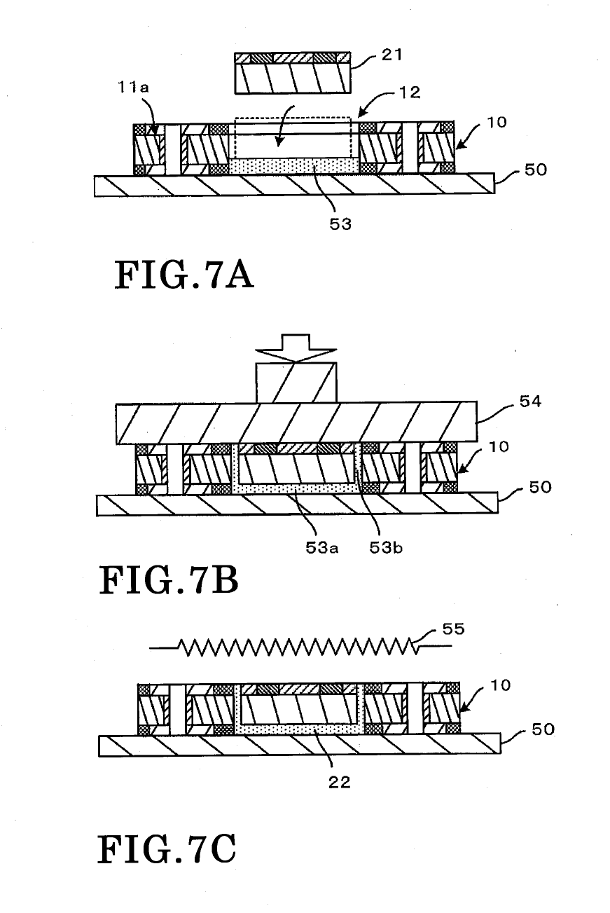

As shown in FIG. 7A, the semiconductor chip 21 is inserted into the through hole 12 from the side of the first surface 11a. In the state, the semiconductor chip 21 is not sunk into the liquid resin 53 to float on the liquid resin by surface tension.

As shown in FIG. 7B, the semiconductor chip 21 is pressed down by a stamper 54. As a result, a part of the liquid resin 53 is leaved in a space between the lower surface of the semiconductor chip 21 and the upper surface of the polyimide sheet 50, the liquid resin 53 other than the part is risen up in a space between the side surface of the semiconductor chip 21 and the side surface of the through hole 12.

The liquid resin 53 leaved in the space between the lower surface of the semiconductor chip 21 and the upper surface of the polyimide sheet 50 is signed as a liquid resin 53a, and the liquid resin 53 risen up in the space between the side surface of the semiconductor chip 21 and the side surface of the through hole 12 is signed as a liquid resin 53b.

In such a manner, the liquid resin 53b is filled in the space between the lower surface of the semiconductor chip 21 and the upper surface of the polyimide sheet 50, concurrently the height from the second surface 11b to the first external electrode 14 is equalized to the height from the second surface 11b to the electrode 23. In other words, the first external electrode 14 and the electrode 23 is configured on the same plane.

In the process, the amount of the droplets of the liquid resin 52 is necessary to preliminarily set that the liquid resin 53b does not overflow from the upper surface of the insulative substrate 11. When the liquid resin 53b overflows from the insulative substrate 11, another process which removing the overflowed resin is added as a wasteful process. Therefore, blocking the waste is necessary to fail-safe.

Accordingly, it is necessary that the amount of the droplets of the liquid resin 52 is nearly equal to sum of a first volume and a second volume, where the first volume is the space between the side surface of the semiconductor chip 21 and the side surface of the through hole 12, and the second volume is the space between the lower surface of the semiconductor chip 21 and the upper surface of the polyimide sheet 50.

In this specification, nearly equal includes not only mathematically equal but also a case of increasing the sum and decreasing the sum described above, where the variation of the sum is in a range of attaining the intention.

As shown in FIG. 7C, the liquid resin 53a leaved in the space between lower surface of the semiconductor chip 21 and the upper surface of the polyimide sheet 50, and the liquid resin 53b filled in the space between the side surface of the semiconductor chip 21 and the side surface of the through hole 12 are hardened by a heater 55, for example.

In such a manner, the side surface of the semiconductor chip 21 is fixed to the side surface of the through hole 12 through the resin 22, concurrently the lower surface of the semiconductor chip 21 is covered with the resin 22.

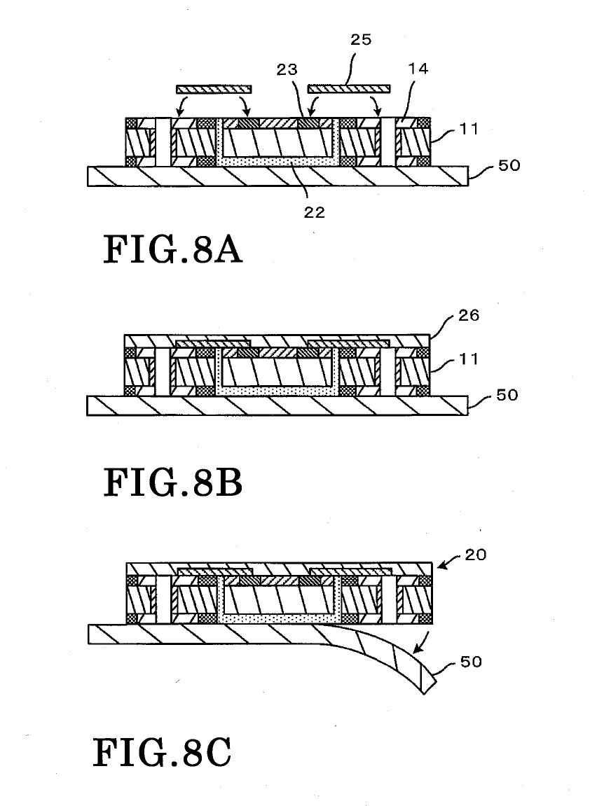

As shown in FIG. 8A, both ends of the connection conductor 25 are bonded to the first external electrode 14 and the electrode 23 by using ultra sonic bonding.

As shown in FIG. 8B, the insulative substrate 11 at the sides of the first surface 11a of the semiconductor chip 21 is covered with the resin 26, for example, an epoxy resin to encapsulate the first external electrode 14, and the connection conductor 25.

As shown in FIG. 8C, the upper surface of the resin 26 is absorbed to be fixed and the polyimide sheet 50 is rolled to separate the semiconductor package 10 from the polyimide sheet 50. In such a manner, the semiconductor device 20 as shown in FIG. 1 is obtained.

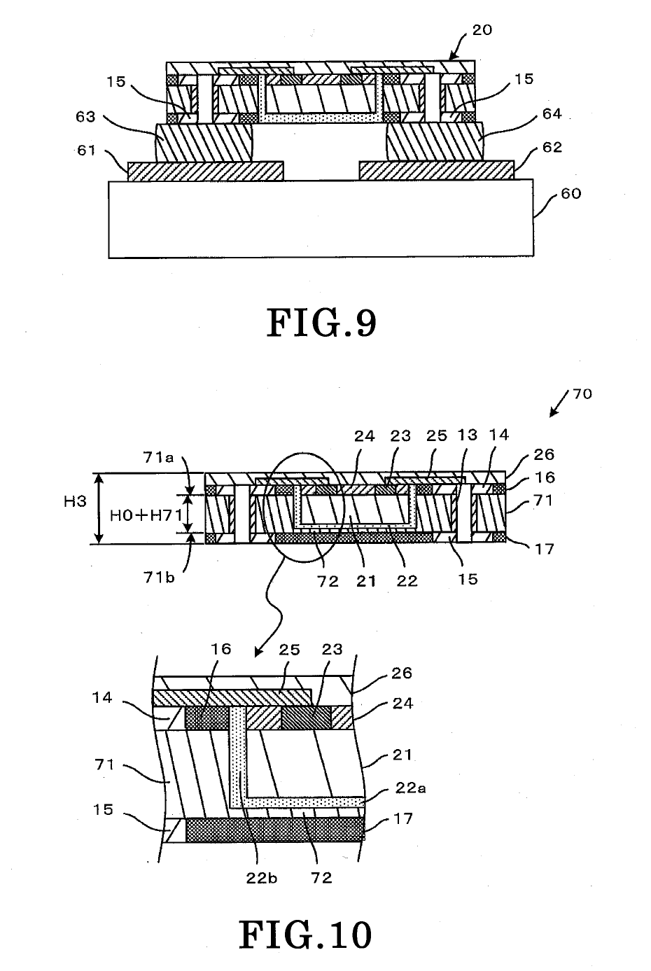

FIG. 9 is a cross sectional views showing the semiconductor device configured on a substrate according to the first embodiment. As shown in FIG. 9, the semiconductor device 20 is disposed to satisfy conditions mentioned below. The second external electrode 15 is disposed on a connection terminal 63 configured on one end of a wiring pattern 61 formed on a wiring substrate 60, and another second external electrode 15 is disposed on a connection terminal 64 configured on one end of a wiring pattern 62 formed on the wiring substrate 60.

The wiring substrate 60 is a glass epoxy substrate, for example. The wiring patterns 61, 62 are formed of copper foils with a thickness of nearly 20 μm, for example, which is stuck by an adhesive material (not shown) with a thickness of nearly 20 μm. The connection terminals 63, 64 are solder pastes with a 100 μm square, for example.

The second external electrodes 15 is solder-bonded to the connection terminals 63, 64 and the semiconductor device 20 is mounted on the wiring substrate 60 by heating the semiconductor device 20 disposed on the wiring substrate 60.

As mentioned above, the semiconductor chip 21 is stored in the through hole 12 of the insulative substrate 11 which has nearly the same thickness as the semiconductor chip, and the semiconductor chip 21 is connected to the second external electrode 15 through the connection conductor 25 which is formed of a planer type, the first external electrode 14 and the conductive body 13 in this embodiment. Further, the upper surface and the lower surface of the semiconductor chip 21 are covered with the resin 26 and the resin 22, respectively.

As a result, a wire for connecting the semiconductor chip 21 to an outer portion and a lead frame as a body for disposing the semiconductor chip 21 are unnecessary, so that the height of the semiconductor device 20 can be sufficiently low and obtain sufficient heat dispassion property. Accordingly, small types of semiconductor package and a semiconductor device, and methods of the semiconductor package and the semiconductor device can be obtained.

A semiconductor device having a length, a width and a height of 2-5 mm, 2-5 mm, and 0.2-1 mm, respectively, for example, can be obtained in this embodiment.

Here, the case that the insulative substrate 11 is the glass epoxy substrate is described, however, another insulative substrate, for example, a bakelite substrate and a resin substrate having thermosetting may be used.

The bakelite substrate has an advantage in which the through hole 12 and the through hole 41 can be formed by a punching process using a press apparatus. The resin substrate having thermosetting has an advantage in which through hole 12 and the through hole 41 can be simultaneously formed with the resin substrate by a transfer mold method using a mold.

A side surface of the through hole 12 is desirable to be a rough surface having concave-convex. The resin 22 flows upwards between the side surface of the semiconductor chip 21 and the side surface of the through hole 12 to be hardened, and the resin 22 thrusts into the concave-convex of the side surface of the through hole 12 to improve the adhesive between the side surfaces of the resin 22 and the through hole 12.

The case in which the conductive body 13 is constituted with a through hole is described, however, a via-hole in which a conductive material is embedded in the through hole 41 can be used. A conductive paste or a thicker film by electro plating as the conductive material, for example, can be used. The via-hole has an advantage in which a conductive resistance is decreased as compared to the through hole.

The case where the connection conductor 25 is bonded by ultra sonic bonding is described, on the other hand, solder bonding can be used. The case where the connection conductor 25 is formed as the conductive plate is described, on the other hand, a plating wiring or a silver-paste wiring can be used. When the connection conductor 25 is formed as the silver-paste wiring, the silver paste can be coated by screen printing, a dispenser or the like. Namely, the second electrode 14 and the electrode 23 are configured in the same plane.

The case is described where the semiconductor chip 21 is inserted into the through hole 12 after the liquid resin 52 is fallen in drops into the through hole 12. On the other hand, semiconductor chip 21 can be inserted into the through hole 12, subsequently, the liquid resin 52 can be fallen in drops into the space between the semiconductor chip 21 and the through hole 12. The method mentioned above is suitable where the space between the semiconductor chip 21 and the through hole 12 is comparatively wider.

When the space is narrower, the liquid resin 52 can be injected into the space between the semiconductor chip 21 and the through hole 12 by using needle. The liquid resin 52 can inserted into the space between the semiconductor chip 21 and the through hole 12 by surface tension.

The case is described where the semiconductor chip 21 is stored in the through hole 12 formed in the insulative substrate 11. On the other hand, the semiconductor chip 21 can be stored in a concave portion formed in the insulative substrate. FIG. 10 is a cross sectional views showing another semiconductor device according to the first embodiment.

As shown in FIG. 10, a concave portion (not shown) is formed in an insulative substrate 71 of a semiconductor device 70 from a side of a first surface 71a. A depth of the concave portion is designed to be nearly equal to a thickness H0 of the insulative substrate 71.

The semiconductor chip 21 is fixed to a side surface of the concave portion and a bottom plate 72 which is a bottom surface of the concave portion through a resin 22a leaved in a space between a lower surface of the semiconductor chip 21 and the bottom plate 72 of the concave portion and a resin 22b filled in a space between the side surface of the semiconductor chip 21 and the side surface of the concave portion.

In such a manner, the thickness of the insulative substrate 71 becomes thicker than a thickness H0 of the insulative substrate 11, where the thickness difference is a thickness H71 corresponding to a thickness of the bottom plate 71. Consequently, the height H3 of the semiconductor device 70 becomes higher than a height H1 of the semiconductor device 20, where the height difference is the thickness H71 corresponding to the thickness of the bottom plate.

However, the semiconductor chip 21 is fixed to both the side surface of the concave portion and the bottom plate 72, so that the lower surface of the semiconductor chip 21 is surrounded by the bottom plate. Accordingly, the structure is stably supported to have an advantage to improve reliability to outer circumstance, for example, moisture transmitting and inserting into the resin 22, and mechanical reliability.

Further, blocking the through hole 12 at the side of the second surface 11b by the polyimide sheet as shown in FIG. 6A can be omitted as the processing steps.

### Second Embodiment

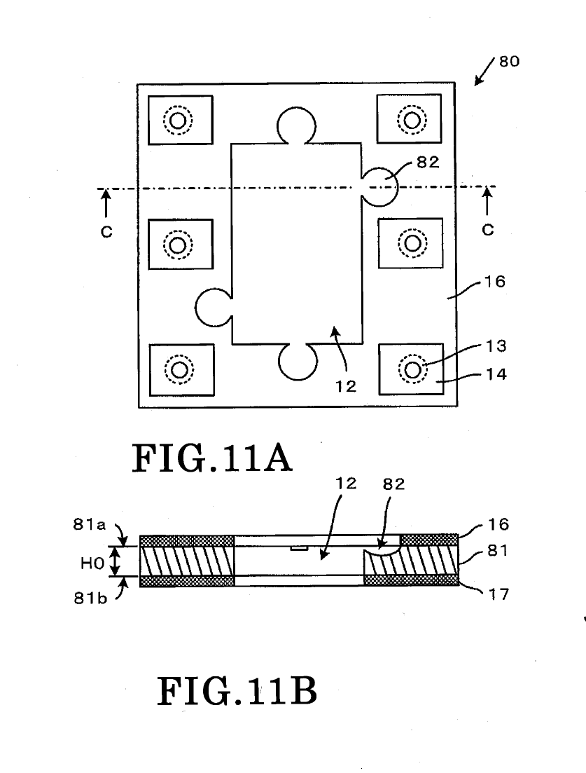

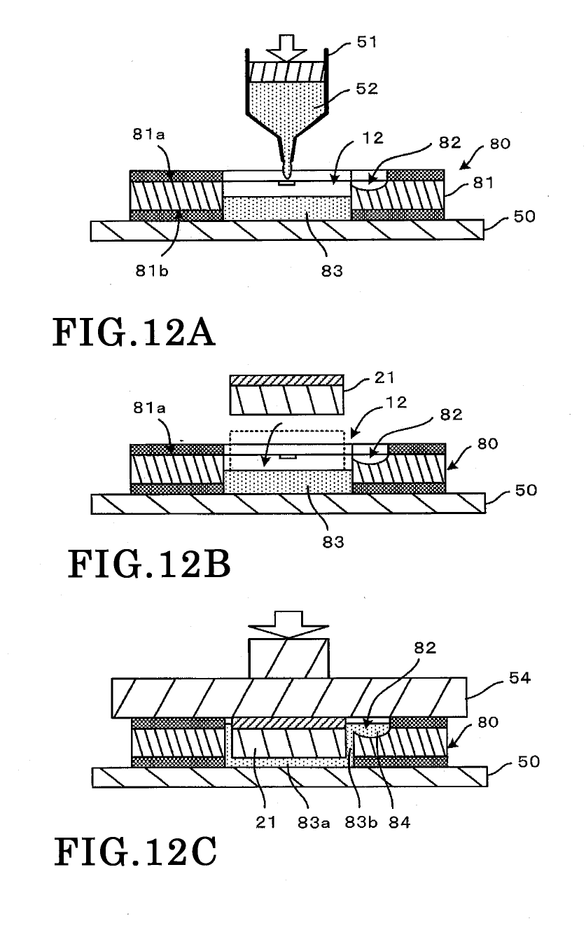

A second embodiment is explained as reference to FIG. 11 and FIG. 12. FIG. 11A is a plane view showing a semiconductor package and FIG. 1B is a cross sectional view showing the semiconductor package cut along the c-c line in FIG. 11A and viewed towards the arrowed direction according to a second embodiment. FIGS. 12A-12C are cross sectional views showing a main portion of a method of fabricating the semiconductor device in an order of processing steps according to the second embodiment.

Throughout the attached drawings in the second embodiment, similar or same reference numerals as the first embodiment shows similar, equivalent or same components. A difference of the second embodiment with the first embodiment is that a pit continuously connected in the through hole is formed in the first surface of the insulative substrate.

As shown in FIG. 11, a plurality of pits 82 continuously connected to an upper end of the through hole 12 are formed in a first surface 81a of an insulative substrate 81 in a semiconductor package 80 in the second embodiment.

The plurality of the pits 82 are formed around the through hole 12. Each of the pit 82 is swept by a drilling the first surface 81a of the insulative substrate 81 to be formed, for example.

The pit 82 acts as a storage tank to storage liquid resin 53b which is overflowed from the through hole 12, when the semiconductor chip 21 is inserted inside the through hole 12 to accidentally make the liquid resin 53b overflow.

As shown in FIG. 12A, a side of the second surface 81b of the insulative substrate 81 including the pit 82 is opposed to the polyimide sheet 50. The semiconductor package 80 is stuck to the polyimide sheet 50 to block the through hole 12 at the side of the second surface 81b by the polyimide sheet 50. Subsequently, the liquid resin 52 is fallen in drops into the through hole 12 by using the dispenser 51 from the side of the first surface 81a.

In the process, a liquid resin 83 may be excessively fallen in drops than a proper amount due to size variation or the like of the semiconductor chip 21.

As shown in FIG. 12B, the semiconductor chip 21 is set to be floated on the liquid resin 83 by surface tension, when the semiconductor chip 21 is inserted into the through hole 12 from the side of the first surface 81a.

As shown in FIG. 12C, when the semiconductor chip 21 is pushed down by a stamper 54, a part of the liquid resin 83a is leaved in a space between the lower surface of the semiconductor chip 21 and the upper surface of the polyimide sheet 50, and the liquid resin 83b other than the part of the liquid resin 83b flows upwards in a space between the side surface of the semiconductor chip 21 and the side surface of the through hole 12.

In the process, when the liquid resin 83 is excess than the proper amount, the liquid resin 83b flows upwards in the space between the side surface of the semiconductor chip 21 and the side surface of the through hole 12 and overflows from the upper end of the through hole 12, so that a liquid resin 84 overflowed is stored in the pit 82. As a result, the resin 84 overflowed is not necessary to be removed to avoid generation of a wasteful process.

Next, as the same as in FIG. 7C, the liquid resin 83a leaved in the space between the lower surface of the semiconductor chip 21 and the upper surface of the polyimide sheet 50, the liquid resin 83b inserted in the space between the side surface of the semiconductor chip 21 and the side surface of the through hole 12 and the liquid resin 84 stored in the pit 82 is hardened.

Next, as the same as in FIG. 8A-8C, the connection conductor 25 is connected to the second electrode 14 and the electrode 23, and the resin 26 is covered with the semiconductor chip 21, the second electrode 14, and the connection conductor 25 to encapsulate the first surface 81a of the insulative substrate 81. Further, the polyimide sheet 50 is removed.

In such a manner, the liquid resin 84 is finally coalesced with the resin 26, so that characteristics of the semiconductor device obtained and the fabricating process is not any obstacle.

As described above, the pit 82 continuously connected to the through hole 12 is formed in the first surface 81a of the insulative substrate 81 in the semiconductor package 80 according to the second embodiment.

As a result, when the liquid resin 83 fallen in drops becomes excess than the proper amount due to the size variation or the like of the semiconductor chip 21 in the process of inserting the semiconductor chip 21 into the through hole 12, the overflowed liquid resin 84 can be stored in the pit 82.

In such a manner, when the resin is accidentally overflowed, the overflowed resin is not necessary to be removed. Consequently, the structure in this embodiment has an advantage that the processing steps can smoothly flow as the wasteful step is not generated.

On the other hand, when the liquid resin 83 fallen in drops is lack to the proper amount, the liquid resin 83b flows upwards in the space between the side surface of the semiconductor chip 21 and the side surface of the through hole 12 cannot reach an upper portion of the semiconductor chip 21.

Accordingly, a contact area between the side surface of the semiconductor chip 21 and the side surface of the through hole 12 is decreased to lower the mechanical strength, so that reliability of the semiconductor device may be an obstacle.

As preparing for the case mentioned above, an amount of the liquid resin 52 fallen in drops can be preliminarily set larger than the nominal case. This approach has an advantage that the problem mentioned above can be avoided as an accidental overflow of the liquid resin generates no problem.

Here, as a size, a number formed in the surface or the like of the pit 82 is not restricted to be able to freely design corresponding to a product target.

### Third Embodiment

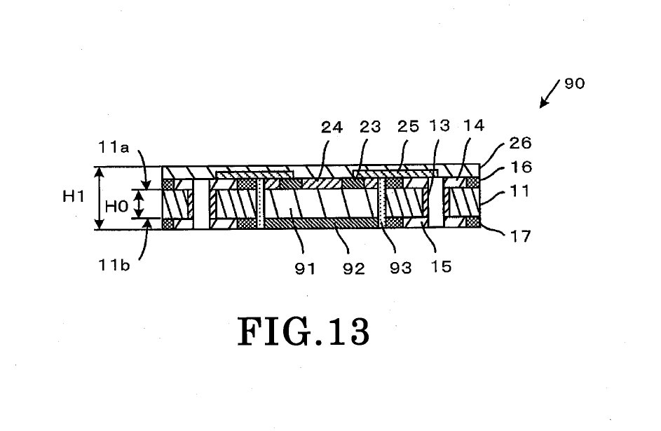

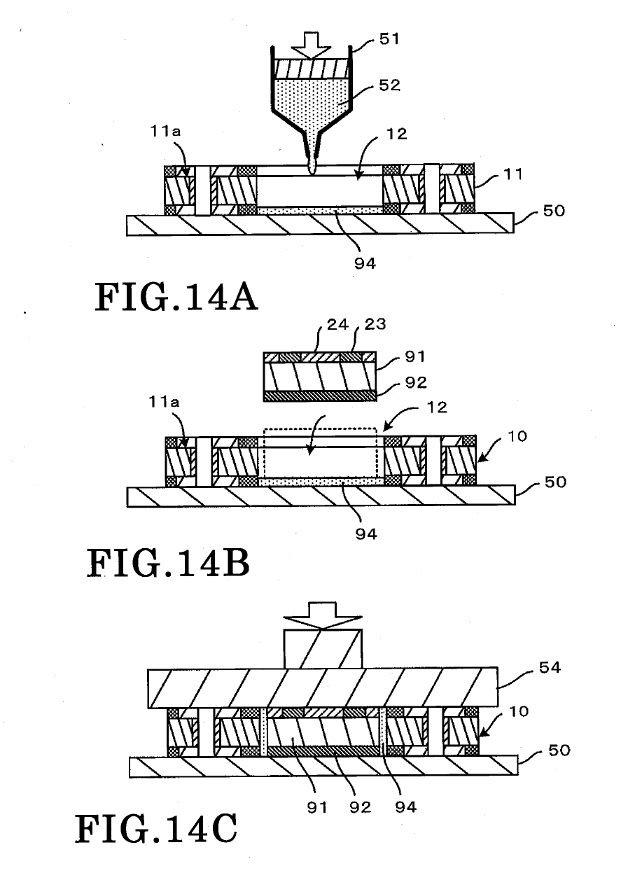

A third embodiment is explained as reference to FIG. 13 and FIG. 14. FIG. 13 is a cross sectional views showing a semiconductor device and FIGS. 14A-14C are cross sectional views showing a method of fabricating the semiconductor device in an order of processing steps.

Throughout the attached drawings in the third embodiment, similar or same reference numerals as the first embodiment shows similar, equivalent or same components. A difference of the third embodiment with the first embodiment is that a vertical semiconductor chip having electrodes on both an upper surface and a lower surface as a semiconductor chip.

As shown in FIG. 13, a semiconductor chip 91 is constituted with a vertical semiconductor chip, for example, a vertical diode or a vertical MOS transistor, having the electrode 23 on an upper surface and an electrode 92 on a lower surface opposed to the upper surface in a semiconductor device 90 according to this embodiment.

semiconductor chip 91 is fixed to the side surface of the through hole 12 through a resin 93 formed in a space between the side surface of the semiconductor chip 91 and the side surface of the through hole 12.

The electrode 92 is formed in all of the second surface 11b of the semiconductor chip 91. A thickness of the electrode 92 is set to be nearly the same as the thickness of the second external electrode 15. In such a manner, a surface of the electrode 92 has nearly the same plane as the surface of the second external electrode 15 to expose on a surface of the semiconductor device 90.

As shown in FIG. 14, the second surface 11b of the through hole 12 in the insulative substrate 11 is blocked by the polyimide sheet 50. Subsequently, the liquid resin 52 is fallen in drops into the through hole 12 from the side of the first surface 11a by the dispenser 51.

In the process, an amount of the liquid resin 52 fallen in drops is set to be nearly equal to a volume of the space between the side surface of the semiconductor chip 91 and the side surface of the through hole 12.

As shown in FIG. 14B, when the semiconductor chip 91 is inserted into the through hole 12 from the side of the first surface 11a, the semiconductor chip 91 is floated on the liquid resin 94 by surface tension.

As shown in FIG. 14C, the semiconductor chip 91 is pressed down by the stamper 54, so that the electrode 92 is stuck to the polyimide sheet 50. Consequently, the space between the electrode 92 and the polyimide sheet 50 is diminished, so that almost liquid resin 94 flows upwards the space between the side surface of the semiconductor chip 21 and the side surface of the through hole 12.

As the same as FIG. 7C, the liquid resin 94 filled in the space between the side surface of the semiconductor chip 21 and the side surface of the through hole 12 is hardened.

As the same as FIGS. 8A-8C, the connection conductor 25 is connected to the second electrode 14 and the electrode 23. The resin 26 is covered with the semiconductor chip 21, the second electrode 14 and the connection conductor 25 to encapsulates the first surface 11a of the insulative substrate 11. Further, the polyimide sheet 50 is removed.

After removing the polyimide sheet 50, the resin on the electrode 92 can be easily removed by acid cleaning when the thin resin is leaved on the electrode 92.

As described above, the electrode 92 is stuck to the polyimide sheet 50 to eliminate the space between the electrode 92 and the polyimide sheet 50 in the third embodiment. Accordingly, the surface of the electrode 92 is not covered with the resin 93, so that the electrode 92 can be exposed on the surface of the semiconductor device 90.

In such a manner, the semiconductor device 90 has an advantage that the vertical semiconductor chip 91 having the electrodes 23, 92 on the upper surface and the lower surface, respectively, is packaged in the semiconductor package 10.

Here, the case is explained as follows. The liquid resin 52 is injected into the through hole 12, subsequently the semiconductor chip 91 is inserted. On the other hand, the semiconductor chip 91 is inserted, subsequently the liquid resin 52 is injected into the space between the side surface of the semiconductor chip 91 and the side surface of the through hole 12 can be used. In the process, a leading edge of the needle of the dispenser 51 is thinned and the liquid resin 52 is injected in a vacuum state.

In such a manner, as a thin resin is not leaved on the electrode 92, cleaning using an acid can be removed. The method having the advantage mentioned above is suitable when the space is comparatively wide.

Further, when a semiconductor package 80 including the pits 82 as shown in FIG. 11, the liquid resin 52 can be fallen in drops in each pit 82 to inject a space between the semiconductor chip 91 and the side surface of the through hole 12 by capillary. The method mentioned above is suitable when the space is comparatively narrow.

While certain embodiments have been described, these embodiments have been presented by way of example only, and are not intended to limit the scope of the inventions. Indeed, the novel devices, packages and methods described herein may be embodied in a variety of other forms; furthermore, various omissions, substitutions and changes in the form of the novel devices, packages and methods described herein may be made without departing from the spirit of the inventions. The accompanying claims and their equivalents are intended to cover such forms or modifications as would fall within the scope and spirit of the inventions.

What is claimed is:

1. A semiconductor package, comprising:
an insulative substrate having a first surface and a second surface opposed to the first surface, a first through hole formed in the insulative substrate from the first surface to the second surface, and a second through hole formed near the first through hole in the insulative substrate from the first surface to the second surface;
a conductive body formed in the vicinity of the second through hole and penetrating into the insulative substrate;
a first external electrode formed on the first surface and connected to an one end of the conductive body; and
a second external electrode formed on the second surface and connected to the other end of the conductive body.

2. The semiconductor package of claim 1, further comprising:
a bottom plane blocking the first through hole at the second surface side of the insulative substrate.

3. The semiconductor package of claim 1, further comprising:
a pit continuously connecting to the first through hole formed on the first surface of the insulative substrate.

4. The semiconductor package of claim 1, wherein
a side surface of the first through hole has concave-convex.

5. The semiconductor package of claim 1, wherein
the conductive body is formed of a conductive material embedded in the second through hole.

6. The semiconductor package of claim 5, wherein
the conductive material is formed as a film by a conductive paste or plating.

7. A semiconductor device, comprising:
an insulative substrate having a first surface and a second surface opposed to the first surface, a first through hole formed in the insulative substrate from the first surface to the second surface, and a second through hole formed near the first through hole in the insulative substrate from the first surface to the second surface;
a conductive body formed in the vicinity of the second through hole and penetrating into the insulative substrate;
a first external electrode formed on the first surface and connected to a one end of the conductive body;
a second external electrode formed on the second surface and connected to the other end of the conductive body;
a semiconductor chip including a first electrode on an upper surface thereof at the first surface side of the insulative substrate, a side surface of the semiconductor chip being fixed through a first resin to a side surface of the through hole; and
a connection conductor electrically connecting between the second electrode and the first electrode.

8. The semiconductor device of claim 7, further comprising:
a second resin formed on the first surface of the insulative substrate to cover the semiconductor chip, the second electrode and the connection conductor.

9. The semiconductor device of claim 7, further comprising:
a bottom plane blocking the first through hole at the second surface side of the insulative substrate.

10. The semiconductor device of claim 7, further comprising:
a pit continuously connecting to the first through hole formed on the first surface of the insulative substrate.

11. The semiconductor package of claim 7, wherein
a side surface of the first through hole has concave-convex.

12. The semiconductor device of claim 7, wherein
the conductive body is formed of a conductive material embedded in the second through hole.

13. The semiconductor device of claim 12, wherein
the conductive material is formed as a film by a conductive paste or plating.

14. The semiconductor device of claim 1, wherein
a thickness of the semiconductor device is 0.2-1 mm.

15. A method of fabricating a semiconductor device, comprising:
preparing a semiconductor package including an insulative substrate having a first surface and a second surface opposed to the first surface, a first through hole formed in the insulative substrate from the first surface to the second surface, and a second through hole formed near the first through hole in the insulative substrate from the first surface to the second surface, a conductive body formed in the vicinity of the second through hole and penetrating into the insulative substrate, a first external electrode formed on the first surface and connected to an one end of the conductive body, and a second external electrode formed on the second surface and connected to the other end of the conductive body;
blocking the first through hole at the second surface side of the insulative substrate by an adhesive sheet;
falling in drops a liquid resin into the first through hole from the first surface side;
inserting a semiconductor chip having a first electrode on an upper surface thereof at the first surface side;
hardening a first portion of the liquid resin which is leaved in a first space between the semiconductor chip and the adhesive sheet, and a second portion of the liquid resin which flows upwards in a second space between a side surface of the semiconductor chip and a side surface of the first through hole,
electrically connecting between the second electrode and the first electrode by a connection conductor.

16. The method of claim 15, wherein
an amount of the liquid resin fallen in the first through hole is nearly equal to sum of a first volume of the first space and a second volume of the second space.

17. The method of claim 15, wherein:
the semiconductor chip has a second electrode on a lower surface opposed to the upper surface.

18. The method of claim 15, further comprising:
forming a pit continuously connecting the through hole on the first surface of the insulative substrate.

19. The method of claim 18, wherein
the pit is received the liquid resin overflowed from the first through hole in inserting the semiconductor chip.

20. The method of claim 15, wherein
falling in drops the liquid resin into the first through hole from the first surface side after inserting the semiconductor chip into the first through hole.
